(19) United States
(12) Patent Application Publication
(10) Pub. No.: US 2003/0063023 A1
(43) Pub. Date: Apr. 3, 2003

(54) Apparatus and method for controlling a stepping motor

(75) Inventors: Chun-Jen Chen, Taichung (TW); Shih-Huang Chen, Hsin-Chu (TW)

Correspondence Address: LOWE HAUPTMAN GILMAN & BERNER, LLP, 1700 Diagonal Road, Suite 310, Alexandria, VA, 22314, US

(73) Assignee: UMAX DATA SYSTEMS INC.

(21) Appl. No.: 09/968,005

(22) Filed: Oct. 2, 2001

(51) Int. Cl. H03M 1/66

(52) U.S. Cl. 341/144

(57) ABSTRACT

An apparatus and a method for controlling a stepping motor are provided. The apparatus comprises a control circuit and a driving device. The control circuit is used to receive a set of input signals in digital form and output an analog signal with a predetermined voltage level equivalent to the set of the input signals in digital form. The driving device with a power source receives the analog signal to serve as a reference voltage and provides a driving current to a stepping motor. The driving current is determined by the analog signal.

### BACKGROUND OF THE INVENTION

1. Field of the Invention

The present invention relates to the control of a motor, especially in relation to the control of a stepping motor used in an image scanner.

2. Description of the Prior Art

In traditional scanners or other kinds of image processing systems like printers, a stepping motor is used as the driving apparatus for moving and position control of the scanning head. The step-by-step driving characteristic of the stepping motor is achieved by the design and wiring of coils on the rotor or the stators.

The configuration of the stepping motor used in the image scanner and the driver of the stepping motor are shown as motor 1 and driver 2 in FIG. 1A. The driver 2 is used to provide the current that drives the motor 1. The driver 2 is usually a set of bipolar transistors or a set of MOSFET's (Metal Oxide Semiconductor Field Effect Transistor). Make use of the 1-phase-winding-model of a stepping motor, the circuit diagram of the motor 1 and driver 2 can be expressed as those in FIG. 1B. The 1-phase-winding-model of the motor 1 in FIG. 1A is shown as motor-model 100 in FIG. 1B and the driver 2 in FIG. 1A is shown as a set of bipolar transistors 102 and 104 in FIG. 1B. As shown in FIG. 1B, the motor-model 100 can be treated as an inductance L in series with a resistor R_{M}. The driving ability, namely the driving torque, of the motor-model 100 is provided by the current through the coil of the stator, i.e., the inductance L, provided by the power source Vₚ. When the bipolar transistor 102 provides current to the base terminal V_{B} of the bipolar transistor 104, the bipolar transistor 104 is turned on and the power source Vₚ provides the driving current to the motor-model 100 to generate driving torque.

FIG. 1C is a functional block diagram of a known driving apparatus used in an image scanner. The driving apparatus includes a control circuit 10, a driving circuit 12, a motor driver 14 and a stepping motor 16. The control circuit 10 is responsive to an input signal for controlling the driving circuit 12. Generally, the control circuit 10 is realized by an application specific integrated circuit (ASIC). The driving circuit 12 is responsive to the control circuit 10 for outputting a reference voltage V_{ref} to the motor driver 14. The motor driver 14 with a power source Vₚ, generally having an output voltage about 12 volts, provides a driving current to the stepping motor 16. The driving current outputted from the motor driver 14 is adjustable by the reference voltage V_{ref} provided by the driving circuit 12. When the output of the power source V_{ref} is insufficient or excess, the driving current can be adjusted and controlled to have a predetermined value by the reference voltage V_{ref}.

FIG. 1D is a circuit diagram of the driving circuit 12. The output of the reference voltage V_{ref} is controlled by turn on/turn off of the switches Q₁, Q₂, Q₃, . . . , and Qₙ₋₁ which are controlled by the control circuit 10 through the control pins, i.e. control 1, control 2, control 3, . . . , and control n−1. The variation of the output of the reference voltage V_{ref} is determined by one of the resistance R₁, R₂, R₃, . . . , and Rₙ₋₁, respectively in series with the switches Q₁, Q₂, Q₃, . . . , and Qₙ₋₁. As the above-mentioned, the driving current through the inductance L, i.e., the coil of the stator, provides the driving torque of the stepping motor. When the driving current is not properly controlled, the driving torque will exceed and cause the stepping motor to generate an acoustic noise and vibration. For the circuit diagram of the driving circuit 12 as shown in FIG. 1D, the output of the reference voltage V_{ref} is limited, and thus making the adjustment of the driving current of the motor driver 14 being limited. Therefore, the acoustic noise and vibration due to the excess driving torque are the problems that usually occur with the stepping motor 16. Furthermore, the control circuit 10, for example, the application specific integrated circuit (ASIC), needs to provide additional output pins to control the turn on/turn off of the switches Q₁ to Qₙ₋₁ of the driving circuit 12, which occupy large areas of the control circuit 10.

Accordingly, it is an intention to provide an improved apparatus for controlling a stepping motor, which can properly control the output of the reference voltage V_{ref} and provides a wider output range of the reference voltage V_{ref} so as to control the stepping motor to work at an optimum state. Hence, the acoustic noise and vibration of the stepping motor due to the excess torque force are eliminated.

### SUMMARY OF THE INVENTION

It is one objective of the present invention to provide an apparatus and a method for controlling a stepping motor, which utilizes a digital-to-analog converter (ADC) with n bits to control the output of a reference voltage V_{ref}, and thereby adjusting a driving current that makes the stepping motor to generate a driving torque. The digital-to-analog converter with n bits can provide the reference voltage V_{ref} with 2ⁿ voltage levels. Therefore, the ability for adjusting the driving current is increased and thus the driving current can be controlled properly to make the stepping motor working at an optimum state.

It is another objective of the present invention to provide an apparatus and a method for controlling a stepping motor, which utilizes a digital-to-analog converter (DAC) established in an application specific integrated circuit (ASIC) to control the output of a reference voltage V_{ref}, so that the application specific integrated circuit does not need to provide additional output pins to control an external circuit, the area of the application specific integrated circuit can be reduced.

In order to achieve the above objectives of this invention, the present invention provides an apparatus and a method for controlling a stepping motor. The apparatus comprises a control circuit and a driving device. The control circuit is used to receive a set of input signals in digital form and output an analog signal with a predetermined voltage level equivalent to the set of the input signals in digital form. The driving device with a power source receives the analog signal to serve as a reference voltage V_{ref} and provides a driving current to a stepping motor. The driving current is determined by the analog signal.

### BRIEF DESCRIPTION OF THE DRAWINGS

The present invention can be best understood through the following description and accompanying drawings, wherein:

FIG. 1A illustrates the functional block diagram of a stepping motor of the image scanner according to the prior art;

FIG. 1B illustrates the circuit diagram of the unipolar driving stepping motor of the image scanner in the prior art;

FIG. 1C illustrates the functional block diagram of a driving apparatus of the image scanner according to the prior art;

FIG. 1D illustrates the circuit diagram of the driving circuit of FIG. 1C;

FIG. 2 is a functional block diagram of a driving apparatus for an image scanner according to the present invention; and

FIG. 3 is a functional block diagram of a driving apparatus for an image scanner according to a preferred embodiment of the present invention.

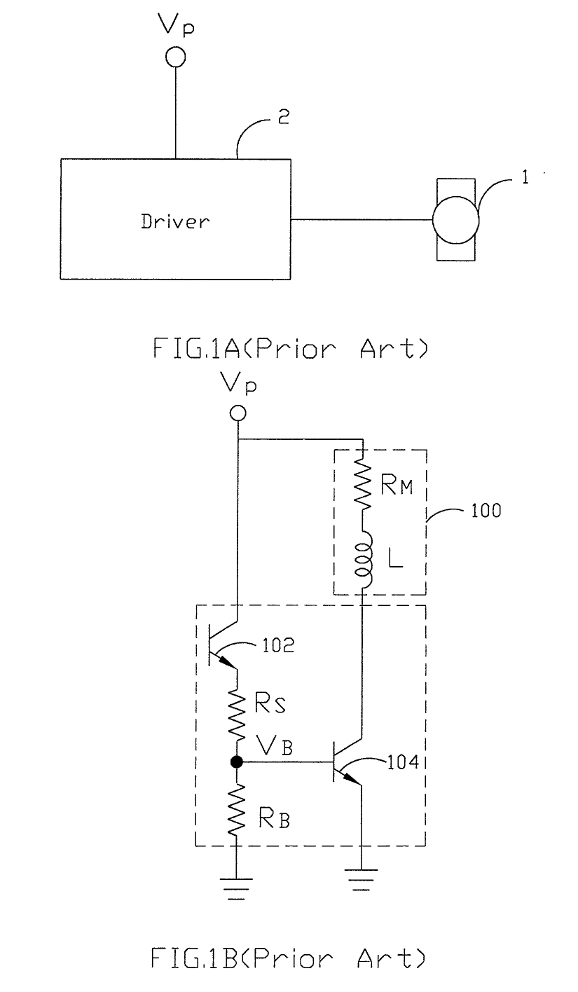

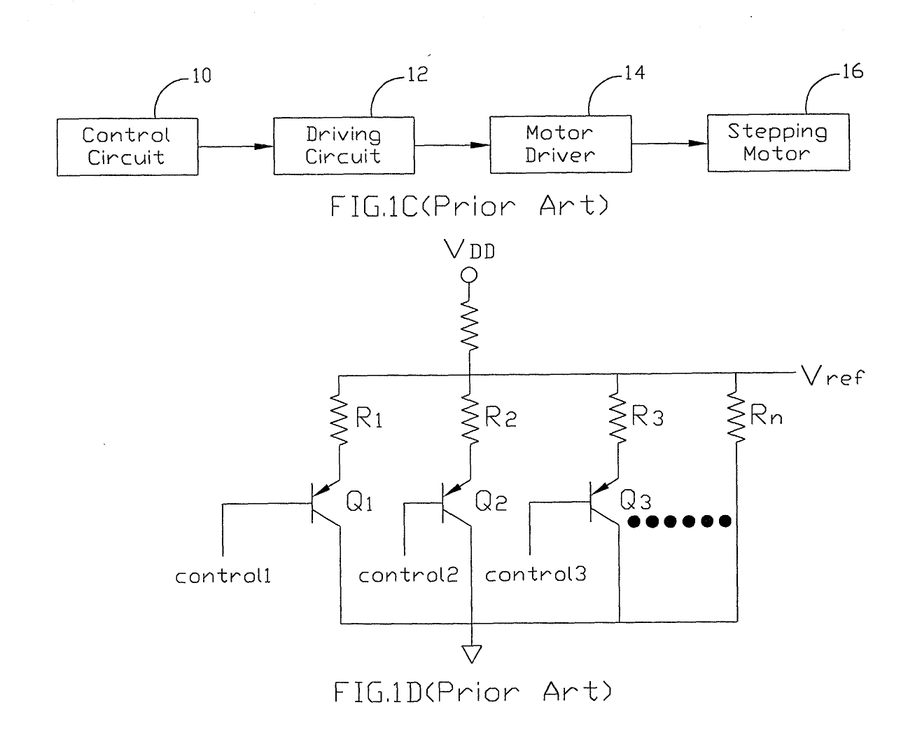

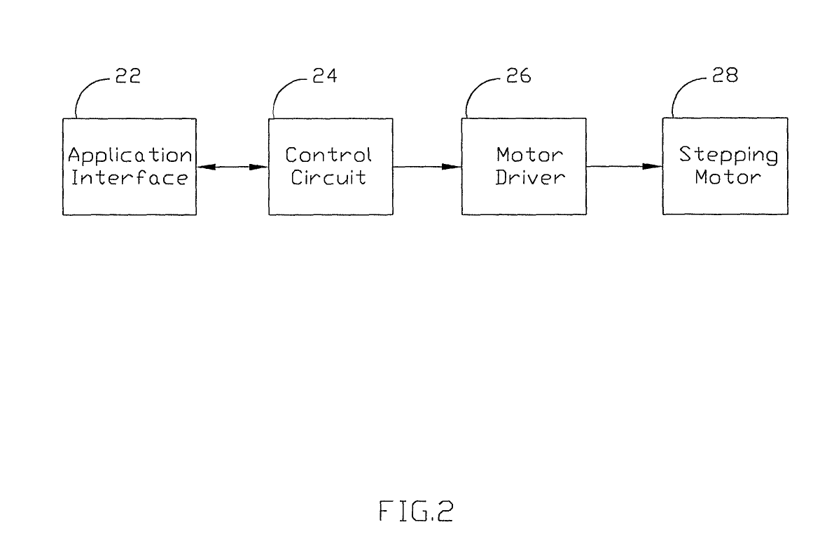

### DESCRIPTION OF THE PREFERRED EMBODIMENT

The present invention provides an apparatus for controlling a stepping motor, especially used in an image scanner. The stepping motor is configured to move the scanning head of the image scanner. The present apparatus is used to provide a driving current to the stepping motor for generating a driving torque. The present apparatus comprises a control circuit and a driving device. The control circuit is used to receive a set of input signals in digital form and thereby output an analog signal with a predetermined voltage level equivalent to the set of input signals. The driving device with a power source Vₚ, receives the analog signal to serve as a reference voltage V_{ref}. The driving device provides a driving current to the stepping motor for generating a driving torque. The reference voltage V_{ref} provided by the analog signal is used to adjust the output of the driving current. The driving ability, namely, the driving torque, of the stepping motor, is provided and determined by the driving current that is controlled by the reference voltage V_{ref}, i.e., the analog signal with the predetermined voltage level.

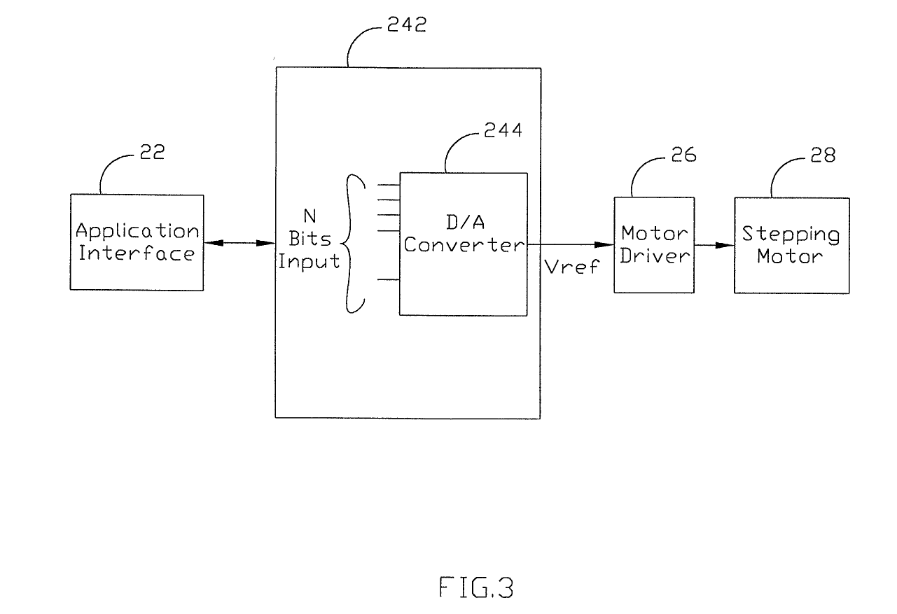

Turning to FIG. 2, a functional block diagram of a driving apparatus, which comprises an application interface 22, a control circuit 24, a stepping motor driver 26 and a stepping motor 28, proposed in the present invention, is illustrated. The control circuit 24 and the stepping motor driver 26 constitute the present apparatus. When a user wants to use the image scanner, the user will choose a specified resolution of the image scanner on the application interface 22, and then begin scanning. The scanning head is thus driven by the stepping motor and moves with a step/or a pitch relating to the corresponding resolution. The relation between the step/or the pitch the scanning head moves and the corresponding resolution is determined by the designer of the image scanner. Once the scanning resolution is selected, the application interface 22 sends a set of digital signals to the control circuit 24. The control circuit 24 converts the set of digital signals to an analog signal with a predetermined voltage level equivalent to the set of digital signals, and then outputs the analog signal to the motor driver 26 to serve as a reference voltage V_{ref} thereof. The reference voltage V_{ref} is used to adjust an output of a driving current of the stepping motor driver 26. The stepping motor driver 26 sends the driving current adjusted by the reference voltage V_{ref} to the stepping motor 28 for generating a driving torque.

The stepping motor driver 26 has a power source Vₚ for providing the driving current to the stepping motor 28. However, the output of the power source Vₚ is not always maintained constant. By way of sending different reference voltages V_{ref} to the stepping motor driver 26, the output of the driving current can be maintained to a predetermined value that makes the stepping motor 28 generating a proper driving torque. For the present invention, the user can input a plurality of sets of digital signals to the control circuit 24 via the application interface 22 to generate different output of the reference voltage V_{ref}.

Referring to FIG. 3, in a preferred embodiment of the present invention, the control circuit 24 is constructed by an application specific integrated circuit (ASIC) 242. A digital-to-analog converter (DAC) 244 with n bits is established in the application specific integrated circuit 242. The digital-to-analog converter 244 with n bits is used to convert a set of digital signals inputted to the application specific integrated circuit 242 to an analog signal with a predetermined voltage level equivalent to the set of digital signals. Because the digital-to-analog converter 244 is provided with n bits, it can accept 2ⁿ sets of digital signals including high logic level “1” and low logic level “0”, and thereby output 2ⁿ analog signals with different voltage levels to the stepping motor driver 26 for serving as the reference voltage V_{ref}. Therefore, the output of the reference voltage V_{ref} can be controlled properly by the digital-to-analog converter 244 to match the variation of the power source Vₚ. The output of the driving current can be adjusted to a proper value by the reference voltage V_{ref} provided by the stepping motor driver 26, and further control the stepping motor working at an optimum state. The acoustic noise and vibration of the stepping motor due to the excess torque force is avoidable. The wider output range of the reference voltage V_{ref} also makes the control of the stepping motor 28 working at an optimum state become easy.

The preferred embodiment is only used to illustrate the present invention; it is not intended to limit the scope thereof. Many modifications of the preferred embodiment can be made without departing from the spirit of the present invention.

What is claimed is:

1. An apparatus for controlling a stepping motor, comprising:
a control circuit for receiving a set of input signals in digital form and outputting an analog signal with a predetermined voltage level equivalent to the set of said input signals in digital form; and
driving means with a power source for receiving said analog signal to serve as a reference voltage and providing a driving current to a stepping motor, wherein said driving current is determined by said analog signal.

2. The apparatus as claimed in claim 1, wherein said control circuit comprises a digital-to-analog converter (DAC) circuit for converting the set of said input signals in digital form to said analog signal with a predetermined voltage level equivalent to the set of said input signals in digital form.

3. The apparatus as claimed in claim 1, wherein said control circuit comprises an application specific integrated circuit (ASIC).

4. The apparatus as claimed in claim 3, wherein said application specific integrated circuit comprises a digital-to-analog converter (DAC) circuit for converting the set of said input signals in digital form to said analog signal with a predetermined voltage level equivalent to the set of said input signals in digital form.

5. An apparatus for controlling a stepping motor used in an image scanner, the stepping motor configured to move a scanning head of the image scanner, said apparatus comprising:
a control circuit for receiving a set of input signals in digital form and outputting an analog signal with a predetermined voltage level equivalent to the set of said input signals in digital form; and
driving means with a power source for receiving said analog signal to serve as a reference voltage and providing a driving current to said stepping motor, wherein said driving current is determined by said analog signal.

6. The apparatus as claimed in claim 5, wherein said control circuit comprises a digital-to-analog converter (DAC) circuit for converting the set of said input signals in digital form to said analog signal with a predetermined voltage level equivalent to the set of said input signals in digital form.

7. The apparatus as claimed in claim 5, wherein said control circuit comprises an application specific integrated circuit (ASIC).

8. The apparatus as claimed in claim 7, wherein said application specific integrated circuit (ASIC) comprises a digital-to-analog converter (DAC) circuit for converting the set of said input signals in digital form to said analog signal with a predetermined voltage level equivalent to the set of said input signals in digital form.

9. A method for controlling a stepping motor, comprising:
inputting a set of digital signals;
outputting an analog signal with a predetermined voltage level equivalent to the set of said digital signals; and
providing a driving current to said stepping motor, wherein said driving current is determined by said analog signal.

10. The method as claimed in claim 9, wherein the set of said digital signals includes signals of high logic level “1” and low logic level “0”.
